(19) United States
(12) Patent Application Publication
(10) Pub. No.: US 2003/0193781 A1
(43) Pub. Date: Oct. 16, 2003

(54) System structure for convenient service access in a rack/cabinet

(76) Inventor: Robert F. Mori, Palo Alto, CA (US)

Correspondence Address: ROSENTHAL & OSHA L.L.P. / SUN, 1221 MCKINNEY, SUITE 2800, HOUSTON, TX, 77010, US

(21) Appl. No.: 10/119,984

(22) Filed: Apr. 10, 2002

(51) Int. Cl. H05K 7/16

(52) U.S. Cl. 361/725

(57) ABSTRACT

A computer system mountable in a support structure includes a primary system structure and a cover. The cover is mountable to the support structure and adapted to receive and support the primary system structure therein. The primary system structure includes a circuit board having at least one electronic device disposed thereon and at least one primary connector coupled thereto. The cover includes at least one reverse primary connector adapted to mate with the at least one primary connector and at least one system connector adapted to mate with at least one cable attachable to the computer system. The primary system structure and cover are adapted to enable translation of the primary system structure with respect to the cover when inserted therein.

### BACKGROUND OF INVENTION

1. Field of the Invention

The invention relates generally to computer system implementation. More particularly, the invention relates to network computer system hardware that is mountable to a support structure and allows for convenient service access to the computer system hardware.

2. Background Art

Network computer systems are computer systems that include the use of one or more servers. These systems may also be referred to as server systems. Several types of servers exists that may be used in a network system, including, but not limited to, file servers that are typically dedicated to storing information, network servers that manage traffic on a computer network, and print servers that manage one or more printers. Server systems typically also include other equipment, such as hard disk drives for memory storage, one or more display screens, and keyboards or other input devices.

The physical configuration of larger server systems becomes important because of the number of servers and other equipment included in the system. Such server systems may occupy large amounts of floor space and may create problems with the space availability in a home and/or offices where the server systems are located.

In recent years, computer system manufacturers have taken steps to reduce the overall system space requirements for server systems. Because of the desire for smaller, more compact systems, attempts have been made to decrease the size of servers and associated equipment while increasing storage capacity of peripheral drives so that fewer drives are required. However, the size and storage capacity of server system components is limited by current technology. Therefore, a number of server system components are often required for a server system and may occupy a considerable amount of floor space.

To reduce the amount of floor space occupied by server systems, computer system manufacturers now typically offer computer equipment that may be mounted in a system support structure, such as a rack, a cabinet, or the like. In general, a rack is a frame or structure to which computer system components may be mounted. Some racks have two vertical rails to which computer equipment is mounted. Other, more common racks have four vertical mounting rails, as shown, for example, in FIG. 1.

As shown in FIG. 1, a rack-mounted computer system 10 typically includes at least one computer system component 15 mounted to a rack 11. The rack includes a plurality of rack rails 11a and is generally referred to as having a front side 12 and a back side 13. The component 15 typically is inserted into and accessed from the front side 12 of the rack 11, and power and connection cables for the component 15 are typically arranged at the back side 13 of the rack 11. The component 15 typically includes brackets (not shown) with holes that extend from each side of the component 15 for mounting the component 15 to the rack 11. The component 15 is typically mounted to the rack 11 by inserting it between rack rails 11a and coupling the brackets to the rack rails 11a, such as by bolts, screws, or the like. The component 15 is typically mounted in the rack 11 with its long axis L1 perpendicular to the front side 12 and back side 13 of the rack 11.

Computer cabinets are enclosed frames that typically include doors and side panels that may or may not be removable. Many cabinets include additional features, such as connections for electrical power, cooling systems with fans and baffles, and electromagnetic interference (EMI) and radio frequency interference (RFI) shielding to meet various system requirements and industry standards.

As shown in FIG. 2, one example of a cabinet-mounted computer system includes a cabinet 20 having computer system components 25 mounted therein. The cabinet 20 includes a rack structure (rack rails 28) surrounded by an enclosure, which includes a top panel 21, bottom panel (not shown), removable side panels 22, a back panel 29 and a front door 29a. The top panel 21 and/or a side panel 22 may be equipped with air vents 23 and 24 to allow for air circulation through the cabinet. Components 25, such as servers, are typically mounted in the cabinet 20 so that a long axis L2 of the component is perpendicular to a front side 26 and back side 29 of the cabinet 20.

Recently, some larger rack systems, such as 4 rack unit (RU) systems offered by Sun Microsystems, Inc. and Compaq Computer Corporation, have been mounted in racks and cabinets using sliding rail systems, which enable extension of a component in and out of the rack without requiring unscrewing and lifting of the component from the rack. For example, as shown in FIG. 1, rails slides 16 may be attached to the sides of the component 15 configured to slide in and out of corresponding rail brackets 17 attached to corresponding sides of the rack 11. Similarly, as shown in FIG. 2, slide brackets 27 may be attached to each side of the component 25 which are configured to mate with and slide along corresponding rail slides (not shown) fixably mounted inside the cabinet 20.

Components mounted in racks using sliding rail systems slide in and out of a rack or cabinet similar to the sliding of a desk drawer. In such systems, cables must be detached from the back of a component before the component can be slid a significant distance out of the rack.

Some sliding rail systems may include a safety catch or other structure to prevent the system from falling out of the rack or cabinet when extended from the rack. For example, as shown in FIG. 1, a sliding rail system may include a catch 18 coupled to an end of the rail bracket 17 and having a portion extending therefrom adapted to engage in an orifice 19 on the rail slides 16 as the component 15 moves into an extended position out of the rack 11. The catch 18 is typically configured to automatically disengage from the orifice 19 when the component 15 is moved back into the rack 11. To remove the component 15 from the rack 11, the catch 18 is manual disengaged from the orifice 19 to allow rail slides 16 to slide in a forward direction with respect to the rail bracket 17.

Although mounting server systems in racks or cabinets may greatly reduce the amount of floor space the systems occupy, it often results in increased service time when a component of a system requires servicing or replacing. For example, for a typical rack-mounted system bolted to a rack, servicing a system component requires, among other steps, (1) disconnecting any cables and the power supply attached to the back of the component, (2) disconnecting the component from the rack or cabinet, (3) removing the component from the rack or cabinet, and (4) finding a suitable surface to place the component on so it can be serviced.

Typically, disconnecting a component from the rack requires unscrewing a number of bolts connecting mounting brackets of the component to the rack rails. Removing a component from the rack typically requires sliding the component out the front of the rack. Also, to service a component, (5) the lid or cover of the component typically has to be removed, such as unscrewed and lifted, to expose the internal elements of the component so faulty items can be replaced or repaired.

After servicing, replacing a component back in a rack system typically requires (6) reattaching the lid of the component, (7) sliding the component back into position in the rack, (8) aligning mounting holes of the component with mounting holes of the rack, (9) securing the component to the rack, such as by replacing the screws or mounting bolts, and (10) reconnecting all of the cables that were disconnected from the component prior to servicing.

These pre-servicing and post-servicing operations, numbered above, often result in significant down time for a system during servicing. This down time may be further amplified in cases in which re-cabling errors are likely to occur, such as when servicing major components of a server system or when servicing a component in a larger server system. When re-cabling errors occur, the system typically must be analyzed to detect and correct the re-cabling errors. This can contribute to significant down time for a system, even when sliding rails are used to facilitate quicker access to a component of the system.

Particularly for many prior art rack and cabinet systems that have multiple components, the cables at the back of the system can frequently become tangled or accidentally pulled out when disconnecting a component of the system for servicing or replacing. One prior art method for reducing tangled cables involves bundling cables together. However, this method results in large cable bundles that can make servicing components and re-cabling more difficult. Bundling cables, in some cases, may result in one or more cables being accidentally disconnected from a component of the system when cables are disconnected from another component for servicing. This, in turn, can lead to increased re-cabling errors.

To avoid such problems, some systems may include a cable management system, such as a cable extender arm or tension reducer, to manage the cables at the back of the system so they do not tense or pull out when the system is slid out the front. Cable extender arms typically are spring loaded metal members that hold a length of cable and extend forward to release slack in the cable when the cable is pulled forward and retract back when tension on the cable is released.

Additionally, Rackable Systems® has recently introduced a compact system configuration that does not require lids for intermediate hardware components in a system grouped in a cluster. In this system, when clusters of components are used, the base of a component above may serve as a lid for the component below it. Although aspects of this system configuration may be adapted to simplify the removal and attachment of lids for a system during servicing, these systems still require disconnecting and reconnecting of the cables at the back of the system each time the system is accessed for servicing.

Thus, a mountable computer system structure that allows for convenient service access to the system and a reduction of disruption time and down time for the system during servicing is desired. Additionally, a mountable computer system which simplifies or reduces the pre-servicing and post-servicing steps required for servicing the system is also desired.

### SUMMARY OF INVENTION

In one aspect, the invention relates to a computer system comprising a primary system structure and a cover. The cover is mountable to a support structure and adapted to support the primary system structure when inserted therein. The primary system structure comprises a circuit board having at least one electronic device disposed thereon and at least one primary connector coupled to the circuit board. The cover comprises at least one reverse primary connector adapted to mate with the at least one primary connector, and at least one system connector configured to mate with at least one cable attachable to the computer system. The primary system structure and cover are also adapted to allow translation of the primary system structure with respect to the cover when the primary system structure is inserted in the cover.

In one aspect, the invention also relates to a method for mounting a computer system in a support structure which includes mounting a cover to the support structure that includes at least one system connector adapted to mate with one or more cables attachable to the computer system and at least one reverse primary connector. The method also includes removably inserting a primary system structure into the cover, wherein the primary system structure includes a circuit board having at least one electronic device disposed thereon and at least one primary connector coupled to the circuit board and configured to mate with the at least one reverse primary connector. The method further includes removably engaging the at least one primary connector with the at least one reverse primary connector, and releasable locking the primary system structure into a fully inserted position in the cover.

In one aspect, the invention also relates to a method for accessing internal components of a computer system mounted in a support structure which includes unlocking from a cover attached to the support structure a primary system structure inserted therein, and disengaging at least one primary connector disposed on the primary system structure from at least one reverse primary connector disposed on the cover. The method additionally includes sliding the primary system structure from an inserted position in the cover to an extended position with respect to the cover to allow access to the internal component so of the system.

In one aspect, the invention also relates to a method for servicing a system which includes a cover mounted to a support structure and a primary system structure inserted in the cover. The method includes disengaging a primary connector disposed on a first primary system structure from a reverse primary connector disposed on the cover, and removing the first primary system structure from the cover. The method further includes inserting a second primary system structure having a primary connector adapted to mate with the reverse primary connector on the cover and engaging the primary connector of the second primary system structure with the reverse primary connector of the cover.

Other aspects and advantages of the invention will be apparent from the following description and the appended claims.

### BRIEF DESCRIPTION OF DRAWINGS

FIG. 1 shows a prior art component mounted in a support structure.

FIG. 2 shows a prior art component mounted in a support structure.

FIG. 3 shows a mountable computer system in accordance with an embodiment of the present invention.

FIG. 4 shows a portion of a mountable computer system in accordance with an embodiment of the present invention wherein system connectors are disposed on a back side of a cover.

FIG. 5 shows a portion of a mountable computer system in accordance with an embodiment of the present invention wherein a reverse primary connector is disposed on an interior surface of a back side of a cover.

FIG. 6A shows a mountable computer system in accordance with an embodiment of the present invention wherein a primary system structure is in a fully inserted position in a cover.

FIG. 6B shows a mountable computer system in accordance with an embodiment of the present invention wherein a primary system structure is in a fully extended position in a cover.

FIG. 6C shows a side view a mountable computer system in accordance with an embodiment of the present invention that includes an injector/ejector mechanism.

FIG. 6D shows a perspective view of the mountable computer system illustrated in FIG. 6C.

FIG. 7 shows a mountable computer system in accordance with an embodiment of the present invention.

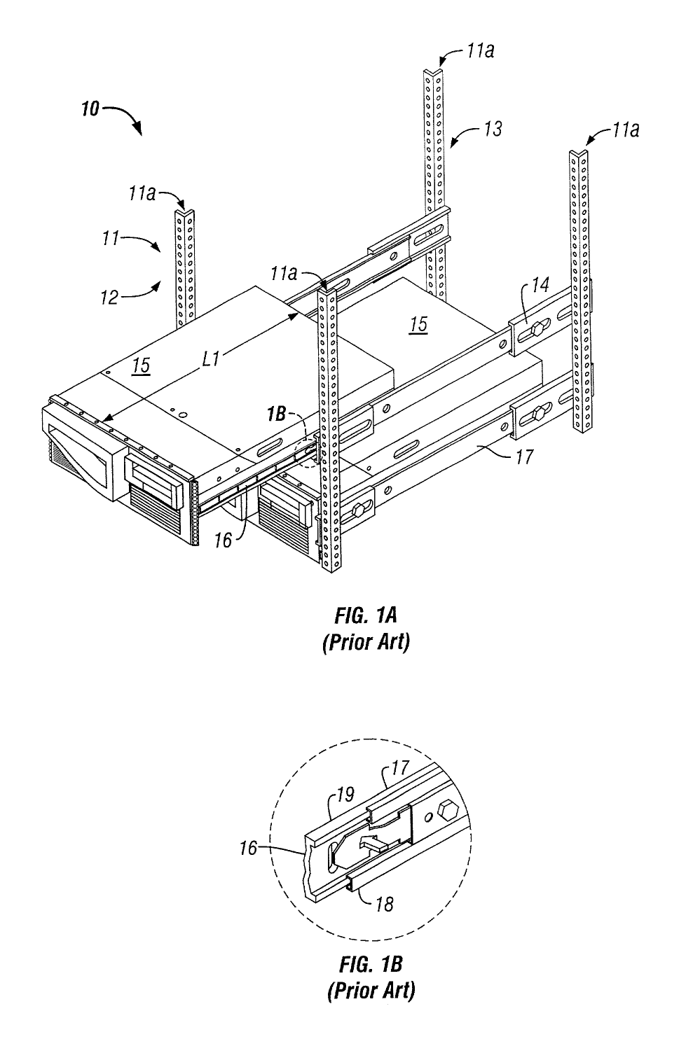

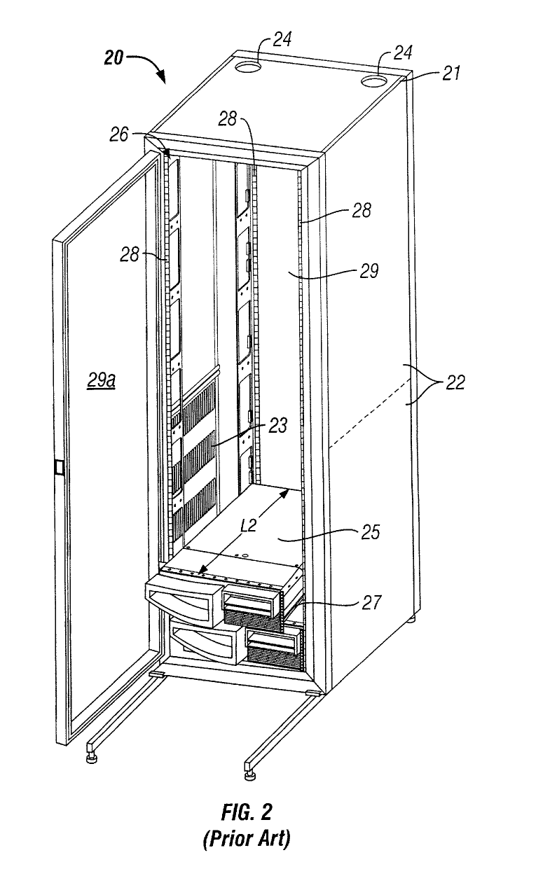

### DETAILED DESCRIPTION

Exemplary embodiments of the present invention will now be described with reference to the accompanying figures.

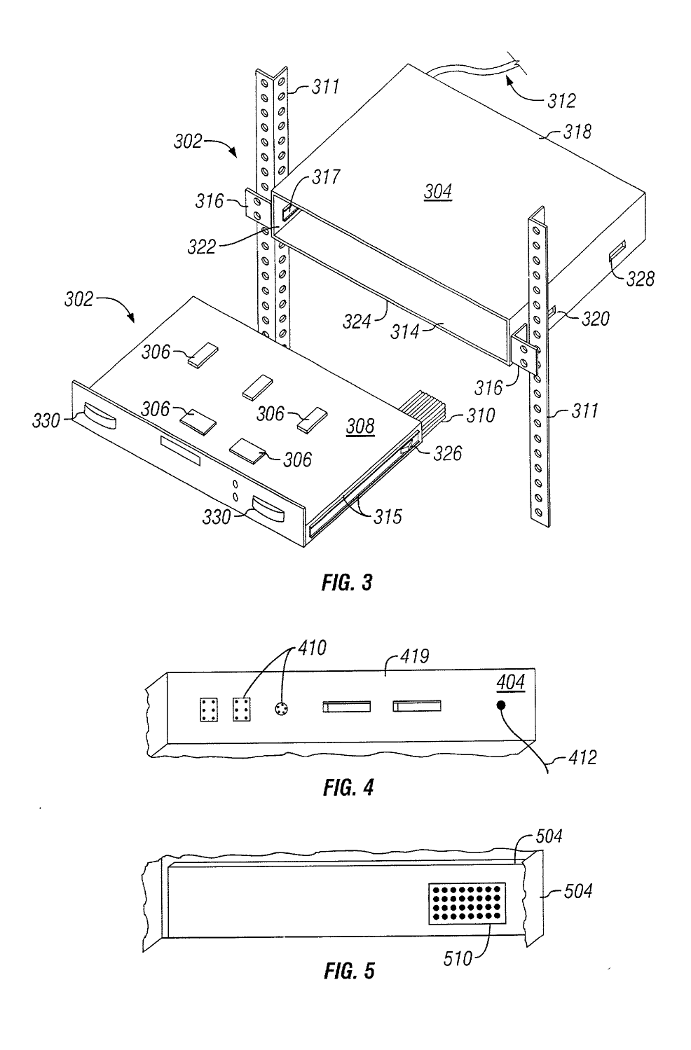

The invention relates to a mountable computer system. The mountable computer system may comprise a server, as illustrated, for example, in FIG. 3. However, those skilled in the art will appreciate that in other embodiments, the mountable computer system may include any computer hardware or related equipment desired to be mounted in a rack, cabinet, or similar support structure. For example, a mountable computer system may include hardware such as a disk drive, keyboard, display screen, or other computer equipment.

In accordance with one exemplary embodiment of the present invention shown in FIG. 3, a mountable computer system 300 comprises a primary system structure 302 and a cover 304. The primary system structure 302 is configured to removably couple to the cover 304. The cover 304 is adapted to be mountable to a support structure 311 and to support the primary system structure 302 when inserted therein. Additionally, the primary system structure 302 and cover 304 are adapted to enable translation of the primary system structure 302 with respect to the cover 304 when the primary system structure 302 is inserted in the cover 304.

As shown in FIG. 3, the primary system structure 302 comprises a circuit board 308 having at least one electronic device 306 disposed thereon and at least one connector 310 (hereafter, primary connector 310) coupled to the circuit board 308. The cover 304 comprises at least one reverse primary connector (shown, for example, at 510 in FIG. 5) adapted to mate with the at least one primary connector 310. The cover 304 further comprises at least one system connector (shown, for example, at 410 in FIG. 4) adapted to mate with at least one cable 312 attachable to the computer system 300.

FIG. 4 shows one example of a system connector 410 disposed on an exterior back surface of a cover 404 in accordance with an embodiment of the invention. FIG. 5 shows one example of a reverse primary connector 510 disposed on an interior surface of a cover 504 in accordance with an embodiment of the invention.

Referring to FIG. 3, in accordance with an exemplary embodiment of the present invention, the primary system structure 302 and cover 304 may be adapted to enable translation of the primary system structure 302 with respect to the cover 304 when inserted therein by disposing a sliding rail system between the primary system structure 302 and the cover 304. For example, rail slides 315 may be provided on opposing exterior side surfaces of the primary system structure 302 and corresponding slide brackets 317 may be provided on corresponding interior side surfaces of the cover 304 such that when the primary system structure 302 is inserted into the cover 304 the slide brackets are adapted to slide along the rails to facilitate translation of the primary system structure 302 in the cover 304. Those skilled in the art will appreciate that in other embodiments, any mechanisms, surface configurations, or means known in the art for mounting a member in translational engagement with another member may be used to enable translation of the primary system structure with respect to the cover without departing from the spirit of the invention. For example, in other embodiments other drawer-type rail mounting system or roller/rail mounting systems may be used.

In one or more embodiments, the cover 304 may comprise a generally hexahedral shaped enclosure having at least three sides defined by walls and an open side 314, referred to as the front side 314, for receiving the primary system structure 302 therein. The at least three sides of the cover 304 may comprise a back side (see 419 in FIG. 4), a right side 320, and a left side 322. In one or more embodiments, the cover may further comprise a top side 318 and/or a bottom side 324. In one or more embodiments, a top side 318 of the cover may be provided by a separate component mounted above the computer system 300, as discussed in the Background section. Additionally, in one or more embodiments, a bottom side 324 of the cover may be provided as a bottom plate on the primary system structure 302 or as part of a separate component mounted below the computer system 300.

As shown in FIG. 4, in one or more embodiments, the one or more system connectors 410 disposed in the cover 404 may be disposed on an outer surface of the back side of the cover 404. In general, the system connectors 410 on the cover 404 are configured to mate with cables 412, such as power cables and/or other component cables from other system hardware and peripheral devices. Those skilled in the art will appreciate that the invention is not limited to the location, configuration, type, or number of system connector 410 on the cover 404.

Referring to FIG. 5, in one or more embodiments, the reverse primary connector 510 that mates with the primary connector (310 in FIG. 3), may be disposed on an interior surface of the back side of the cover 504. The primary system structure and the cover 504 being adapted such that a mating of the primary connector (310 in FIG. 3) with the reverse primary connector 510 results in a coupling of the primary system structure (302 in FIG. 3) to any power supply and/or other cables coupled to the cover 504 via the system connector(s) (410 in FIG. 4). This type of “quick connect” or “plug-and-play” arrangement between the primary system structure and the cover, advantageously, allows for easy connection and disconnection of the primary system structure with the cover. This arrangement permits convenient servicing, or the like, of the primary system structure, without requiring disconnection and reconnection of any cables at the back of the system.

Those skilled in the art will appreciate that the invention is not limited to a location, type, configuration, or number of reverse primary connector(s) 510 of the cover 504. Additionally, in one or more embodiments, the system connector may include a power cable extending from the cover with a connector at its distal end adapted to couple to a power supply.

Referring back to FIG. 3, the cover 304 may further comprise at least one attachment 316 for securing the cover 304 to a support structure 311, such as a rack, cabinet, or the like. In the embodiment shown in FIG. 3, the at least one attachment 316 comprises conventional rack ears commonly used to attach computer system components to support structures. In this embodiment, the attachments 316 extend from opposing sides of the cover 304 proximal the front side 314 of the cover 304. The attachments 316 include holes for screwing, bolting, or otherwise securing the cover 304 to the support structure 311, which has corresponding holes therein. Those skilled in the art will appreciate that the invention is not limited to the type of attachment method shown in FIG. 3. In one or more embodiments, any attachment method known in the art may be used to attach a cover to a support structure in accordance with the invention.

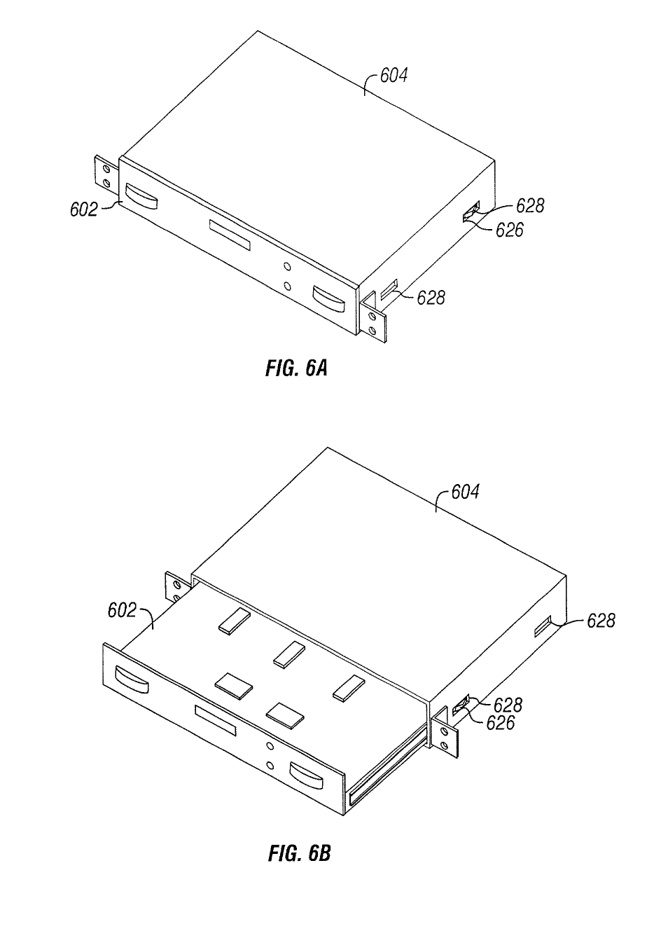

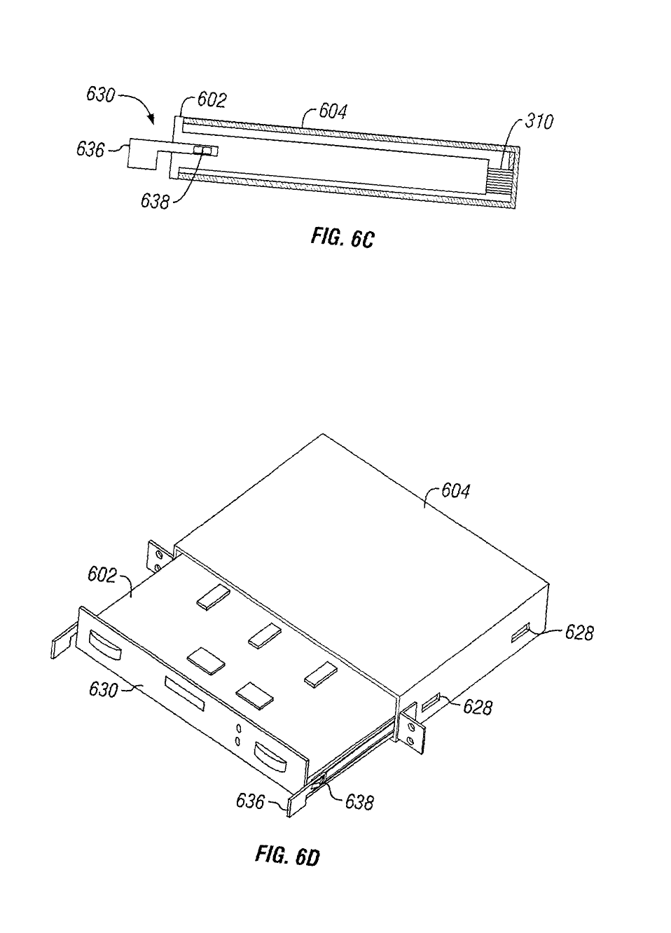

Referring to FIGS. 6A and 6B, in accordance with one or more embodiments of the present invention, the primary system structure 602 and cover 604 also may be adapted to allow relatively unconstrained translation of the primary system structure 602 between a fully inserted position in the cover 604, (illustrated, for example, in FIG. 6A) and a fully extended position in the cover 604 (illustrated, for example, in FIG. 6B). A fully inserted position may be any position which enables the covering of the internal components (i.e., circuit board and at least one electronic device) of the system by the cover 604 and engagement of the primary connector (e.g., 310 in FIG. 3) with the reverse primary connector (e.g., 510 in FIG. 5). A fully extended position may be any position in results in or allows disengagement of the primary connector (e.g., 310 in FIG. 3) from the reverse primary connector (e.g., 510 in FIG. 5) and access to the components intended to be serviced in the system. In some embodiments, the primary system structure 602 and cover 604 may be configured to include intermediate extended positions between the fully inserted position and the fully extended position of the primary system structure 602 with respect to the cover 604.

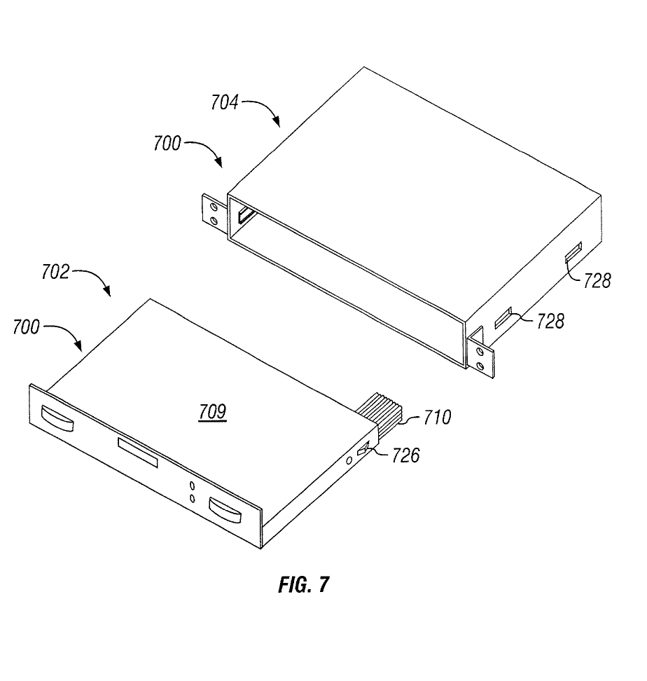

In one or more embodiments, the primary system structure 602 and the cover 604 also may be adapted such that the primary system structure 602 releasably locks in place in the cover 604, such as by a securing mechanism, when it is in the fully inserted position in the cover. For example, as shown in FIG. 6A, when the primary system structure 602 is moved into the fully inserted position in the cover 604, a latching mechanism 626 (see also 326 in FIG. 3 or 726 in FIG. 7) on at least one side of the primary system structure 602 may move into alignment with a corresponding orifice 628 or recess in the cover 604 and releasably engage with the orifice 628 or recess. In such case, to release engagement of the latching mechanism 626 with the orifice 628, the latching mechanism 626 may be depressed inward to disengage it from the orifice 628 and allow the primary system structure 602 to translate with respect to the cover 604. Those skilled in the art will appreciate that the invention is not limited to the type of method or mechanisms used for releasably locking the primary system structure 602 in place in the cover 604. For example, numerous securing mechanisms, such as releasable latching mechanisms and latching configurations (e.g., locking shoulders) are well known in the art and may be used as desired without departing from the spirit of the invention.

In one or more embodiments, the primary system structure 602 and the cover 604 also may be adapted to prevent the primary system structure 602 from accidentally falling out of the cover when the primary system structure 602 is moved to the fully extended position. For example, the primary system structure 602 may releasably lock in place in the cover 604, such as by a securing mechanism, when moved to the fully extended position. For example, as shown in FIG. 6B, when the primary system structure 602 is moved into the fully extended position in the cover 604, at least one securing mechanism, such as latching mechanism 626 (see also 326 in FIG. 3 or 726 in FIG. 7) on at least one side of the primary system structure 602 may move into alignment with an orifice 628 or recess in the cover 604 and releasably engage with the orifice 628 or recess. In such case, to release engagement of the latching mechanism 626 with the orifice 628, the latching mechanism 626 may be depressed inward to disengage it from the orifice 628 and allow the primary system structure 602 to translate further in or out of the cover 604. In one or more embodiments, the latching mechanism 626 may be configured to only engage with a corresponding orifice 628 when the primary system structure 602 is moved in an extended direction with respect to the cover 604. Those skilled in the art will appreciate that the invention is not limited to the type of method or mechanism for releasably locking the primary system structure 602 in place in the cover 604. For example, numerous securing mechanisms, such as releasable latching mechanisms and latching configurations (e.g., locking shoulders) are well known in the art and may be used without departing from the spirit of the invention.

Referring to FIGS. 6C and 6D, in accordance with one or more embodiments of the invention, the mountable computer system 600 may further comprise an injector/ejector mechanism 630 to assist in injection and/or ejection of the primary system structure 602 in or out of the cover 604. For example, a face plate having injector/ejector handles 636 may be disposed on a front side 630 of the primary system structure 602. The injector/ejector handles 636 may be positioned on the right and left sides of the face plate and may include an outward facing protrusion 638 which can be moved into locking engagement with an orifice 628 or recess in the cover 604. To engage the primary system structure 602 in releasable locking engagement with the cover 604, a force may be applied to each injector/ejector handle 636 to push the primary system structure 602 into the fully inserted position in cover 604 and rotate the injector/ejector handles 636 inward toward each other until they are flat against the face plate. The rotation of the injector/ejector handles 636 against the face plate also results in engagement of the protrusion 638 on the sides of the handles 636 with the orifices 628 in the cover 604. To release the primary system structure 602 from the cover 604, a force may be applied to the injector/ejector handles 636 to rotate them away from each other and the face plate, which disengages the protrusions 638 from the orifices 628, thereby ejecting the primary system structure 602 from locking engagement with the cover 604. Once the injector/ejector handles 636 are released from locking engagement with the cover 604, they may be used to pull the primary system structure 602 from the inserted position in the cover 604.

Those skilled in the art will appreciate that in other embodiments, any injector or ejector mechanisms may be used to assist in the engagement or disengagement of the primary system structure 302 with the cover 304. Numerous types of injector/ejector mechanisms are well known in the art for this purpose, such as those marketed as sold by One Stop Systems in Escondido, Calif.

Referring to FIG. 7, in one or more embodiments of the present invention, the primary system structure 702 may further include a protective housing 709 that covers a portion of the circuit board (for example, 308 in FIG. 3) so that select electronic components mounted on the circuit board are not readily visible from an external surface of the primary system structure 702. For example, in situations where adverse ambient conditions may cause damage to an electronic component, a protective housing 709 may be desired to provide additional protection for components of the primary system structure 702. In the embodiment shown, the primary connector 710 of the primary system structure 702 extends from the housing 709 to mate with the corresponding reverse connector (not shown) of the cover 704. Primary system structures including a protective housing 709 may be quickly removed upon failure and replaced by a new primary system structure to minimize the downtime for servicing. Primary system structures removed for servicing may be repaired at a remote location for later use or discarded upon failure, as determined by a system designer or service technician. In one or more embodiments, the protective housing may be configured to be easily opened or removed for servicing to allow for servicing of the primary system structure on site, if desired. Advantageously, providing a system structure that enables quick removal and replacement of the primary system structure during servicing may minimize the downtime associated with servicing a major component of a system.

Those skilled in the art will appreciate that in accordance with embodiments of the invention described above, a primary system structure or the entire system may be completely removed from the rack for servicing, as is currently done with existing systems. For instance, when a system is mounted in a high position in a support structure, complete removal of the primary system structure from the cover may be chosen for convenience. As noted for one or more embodiments above, the system may be configured such that complete removal of the system from the support structure requires a second deliberate operation, such as disengagement of a securing mechanism that automatically activates when the system is pulled out into the fully extended position. Such safety features are commonly used in prior art drawer structures to prevent drawers from falling out when pulled into a fully extended position. Any conventional safety feature that allows for complete removal of the primary system structure from the cover may be used with embodiments of the invention as desired.

In one aspect, the present invention provides a method for mounting a system in a support structure for convenient service access to the system. The method includes mounting a cover of the system to the support structure. The cover having at least one system connector configured to mate with at least one cable attachable to the system and at least one reverse primary connector. The method also includes removably inserting a primary system structure into the cover. The primary system structure comprises a circuit board having at least one electronic device attached thereto and at least one primary connector coupled to the circuit board and configured to mate with the at least one reverse primary connector of the cover. The method further includes removably engaging at least one primary connector of the primary system structure with the at least one reverse primary connector of the cover and releasably locking the primary system structure in a fully inserted position in the cover.

In one aspect, the present invention also provides a method for conveniently accessing internal components of a system mounted in a support structure. The method includes unlocking a primary system structure from a corresponding cover attached to the support structure. The method also includes disengaging at least one primary connector of the primary system structure from at least one reverse primary connector of the cover and sliding the primary system structure from an inserted position in the cover to an extended position with respect to the cover to allow access to the internal components of the system. The method may further include releasably locking the primary system structure in the extended position in the cover. The method may also further include sliding the primary system structure from the extended position in the cover to the inserted position in the cover, engaging the at least one primary connector with the at least one reverse primary connector, and releasably locking the primary system structure in the inserted position in the cover.

In one aspect, the present invention also provides a method for servicing a computer system including a cover mountable to a support structure and a primary system structure inserted therein. The cover includes at least one system connector adapted to mate with cables attachable to the system. In one or more embodiments, the method includes disengaging a primary connector disposed on a first primary system structure from a reverse primary connector disposed on the cover and removing the first primary system structure from the cover. The method further includes inserting a second primary system structure having a primary connector adapted to mate with the reverse primary connector of the cover and engaging the primary connector of the second primary system structure with the reverse primary connector.

In accordance with one or more embodiments of the invention, because the invention provides for the direct connection of cables to the cover of the mountable computer system and the cover is configured to remain attached to the support structure when the primary system structure is extended or removed from the cover, cables may remain connected to the system cover during servicing of the primary system structure.

Advantages of the present invention may include ore or more of the following in one or more embodiments. Because the cables attached to the back of the cover do not require disconnection when the primary system structure is disconnected from the cover for servicing cable disconnection and re-cabling errors are avoided. The primary system structure can be reattached to the cables and power supply at the back of the system by simply pushing it into a fully inserted position in the cover to engage its at least one primary connector with the at least one reverse primary connector of the cover. In this way, reconnection of the primary system structure is similar in function to a “plug-and-play” component of a conventional desktop computer.

In accordance with one or more embodiments of the invention, by providing at least one primary connector on the primary system structure that couples to at least one reverse primary connector on the cover, the primary system structure may be unplugged from all components connected to the system in a single step of disengaging the primary system structure from the cover fixed to a support structure. This allows for disconnection of the component from other components of the system without requiring the unplugging of any cables on the backside of the cover. This feature of the present invention not only saves down time for the system during servicing, but also eliminates the potential for errors during re-cabling of the system after servicing. Those skilled in the art will appreciate that, if desired, any additional features, such as a cable management system or tension reducer system, may be used with embodiments of the invention to further assist in the management of cables attached to the system.

Further, in accordance with one or more embodiments of the invention, by providing a primary system structure that can translate with respect to a cover which remains attached to a support structure, server components, such as disk drives, chips, or memory, may be added, removed, or serviced by simply moving the primary system structure to an extended position in the cover, as shown in FIG. 6A. Alternatively, the primary system structure may be removed and replaced with a new primary system structure to significantly reduce the downtime associated with servicing system components. The primary system structure removed for servicing can then be serviced without resulting in significant downtime for the system. In both cases, the pre-servicing and post-servicing steps for a mounted computer system may be essentially reduced to opening and closing a drawer.

In one or more embodiments, features such as ejector handles may be used to securely snap the primary system structure in and out of its locked position with the cover. In one or more embodiments of the present invention not only may the inefficient use of floor space be overcome, but also problems associated with incorrect re-cabling of components after servicing. In accordance with one or more embodiments of the present invention, the only time the cables have to be disconnected from the system is when the system cover needs to be replaced by a new system cover. In accordance with one or more embodiments, the time required for servicing components is reduced and the need to find an area to place a system on for servicing can be eliminated.

While the invention has been described with respect to a limited number of embodiments, those skilled in the art, having benefit of this disclosure, will appreciate that other embodiments can be devised which do not depart from the scope of the invention. Accordingly, the scope of the invention should be limited only by the attached claims.

What is claimed is:

1. A computer system mountable to a support structure, comprising:
a primary system structure including a circuit board having at least one electronic device disposed thereon and at least one primary connector coupled to the circuit board; and
a cover attachable to the support structure and adapted to support the primary system structure when inserted therein, the cover including at least one reverse primary connector adapted to mate with the at least one primary connector, and at least one system connector adapted to mate with at least one cable attachable to the computer system, the cover and the primary system structure adapted to enable translation of the primary system structure with respect to the cover when the primary system structure is inserted in the cover.

2. The computer system of claim 1, wherein the cover further comprises a generally hexahedral shaped enclosure having at least three sides comprising walls and an open front side for receiving the primary system structure therein.

3. The computer system of claim 2, wherein the at least three sides comprise a back side, a right side, and a left side.

4. The computer system of claim 3, wherein the at least three sides further comprises a top side and a bottom side.

5. The computer system of claim 3, wherein the at least one system connector is disposed on an outer surface of the back side of the cover.

6. The computer system of claim 3, wherein the at least one reverse primary connector is disposed on an inner surface of the back side of the cover.

7. The computer system of claim 1, wherein the primary system structure further comprises a protective housing covering at least a surface of the circuit board and the at least one primary connector is accessible outside of the protective housing.

8. The computer system of claim 7, wherein the at least one primary connector extends from the protective housing.

9. The computer system of claim 7, wherein the at least one primary connector is disposed in an exterior surface of the protective housing.

10. The computer system of claim 1, wherein the primary system structure and the cover are adapted to enable translation of the primary system structure between a fully inserted position in the cover and a fully extended position with respect to the cover.

11. The computer system of claim 10, wherein the primary system structure and the cover are adapted such that the primary system structure releasably locks in place in the cover when in the fully inserted position.

12. The computer system of claim 10, wherein the primary system structure further comprises at least one securing mechanism which releasably engages with the cover when the primary system structure is moved into the fully inserted position in the cover.

13. The computer system of claim 10, wherein the primary system structure and the cover are adapted to prevent the primary system structure from falling out of the cover when the primary system structure is moved to the fully extended position in the cover.

14. The computer system of claim 10, wherein the primary system structure further comprises at least one securing mechanism which releasably engages with the cover when the primary system structure is moved into the fully extended position in the cover.

15. A computer system, mountable in a support structure the computer system comprising:
a primary system structure including a circuit board having at least one electronic device disposed thereon and at least one primary connector coupled to the circuit board; and
a cover mountable to a support structure and adapted to support the primary system structure when inserted therein, the cover including a generally hexahedral shaped enclosure having a top side, a bottom side, a right side, a left side and a back side comprising walls and an open front side for receiving the primary system structure therein, the cover also including at least one reverse primary connector disposed on an interior surface of the back side and adapted to mate with the at least one primary connector, and least one system connector disposed on an exterior surface of the back side of the cover and configured to mate with at least one cable attachable to the computer system,
wherein the primary system structure and cover are adapted to enable translation of the primary system structure between a fully inserted position and a fully extended position in the cover, and the primary system structure and the cover are adapted such that the primary system structure releasably locks in place in the cover when in the fully inserted position and when in the fully extended position in the cover.

16. The computer system of claim 15, wherein the primary system structure further comprises a protective housing covering a surface of the circuit board and the at least one primary connector extends from a back surface of the protective housing.

17. A method for mounting a system in a support structure, comprising:
mounting a cover to the support structure, the cover including at least one system connector configured to mate with at least one cable attachable to the system and at least one reverse primary connector;
removably inserting a primary system structure into the cover, the primary system structure including a circuit board having at least one electronic device disposed thereon and at least one primary connector coupled to the circuit board and configured to mate with the at least one reverse primary connector;
removably engaging the at least one primary connector with the at least one reverse primary connector; and
releasably locking the primary system structure in a fully inserted position in the cover.

18. A method for accessing internal components of a system mounted in a support structure, the method comprising:
unlocking from a cover attached to the support structure a primary system structure inserted therein;
disengaging at least one primary connector disposed on the primary system structure from at least one reverse primary connector disposed on the cover; and
sliding the primary system structure from an inserted position in the cover to an extended position with respect to the cover to allow access to the internal components of the system.

19. The method of claim 18, further comprising releasably locking the primary system structure in the extended position in the cover.

20. The method of claim 18 further comprising:
sliding the primary system structure from the extended position in the cover to the inserted position in the cover;
engaging the at least one primary connector with the at least one reverse primary connector; and
releasably locking the primary system structure in the inserted position in the cover.

21. A method for servicing a system including a cover mounted to a support structure and a primary system structure inserted therein, the method comprising:
disengaging a primary connector disposed on a first primary system structure from a reverse primary connector disposed on the cover;
removing the first primary system structure from the cover;
inserting a second primary system structure having a primary connector adapted to mate with the reverse primary connector on the cover;
engaging the primary connector of the second primary system structure with the reverse primary connector.
